(19) United States
(12) Patent Application Publication
(10) Pub. No.: US 2025/0311362 A1
(43) Pub. Date: Oct. 2, 2025

(54) HIGH VOLTAGE SEMICONDUCTOR DEVICE AND METHOD OF MANUFACTURING SAME

(71) Applicant: DB HiTek Co., Ltd., Bucheon-si (KR)

(72) Inventor: Min Woo KIM, Incheon (KR)

(21) Appl. No.: 18/662,597

(22) Filed: May 13, 2024

(30) Foreign Application Priority Data
Mar. 28, 2024 (KR) 10-2024-0042320

(51) Int. Cl. H01L 29/40; H01L 29/66; H01L 29/78

(52) U.S. Cl. CPC H10D 64/112; H10D 30/0227; H10D 30/0285; H10D 30/65; H10D 64/115

(57) ABSTRACT

Proposed are a high voltage semiconductor device and a method of manufacturing the same and, more particularly, a high voltage semiconductor device and a method of manufacturing the same seeking to improve on-resistance (Rsp) characteristics of the device by forming a field plate on a substrate and above a gate region, and prevent deterioration of HE-SOA characteristics by forming a thin film-shaped gate field plate below the gate region to mitigate an electric field concentrated below the field plate and on an edge of the gate region.

### CROSS-REFERENCE TO RELATED APPLICATION

The present application claims priority to Korean Patent Application No. 10-2024-0042320, filed Mar. 28, 2024, the entire contents of which is incorporated herein for all purposes by this reference.

### BACKGROUND OF THE INVENTION

### Field of the Invention

The present disclosure relates to a high voltage semiconductor device and a method of manufacturing the same and, more particularly, to a high voltage semiconductor device and a method of manufacturing the same seeking to improve on-resistance (Rsp) characteristics of the device by forming a field plate on a substrate and above a gate region, and prevent deterioration of HE-SOA characteristics by forming a thin film-shaped gate field plate below the gate region to mitigate an electric field concentrated below the field plate and on an edge of the gate region.

### Description of the Related Art

A lateral double-diffused metal oxide semiconductor (LDMOS) is a representative power device with fast switching response and high input impedance. Hereinafter, the structure and manufacturing process of a typical LDMOS device will be described in detail.

FIG. 1 is a cross-sectional view showing a conventional high voltage semiconductor device.

Referring to FIG. 1, in a conventional high voltage semiconductor device 9, within a substrate 901, a drift region 910 and a body region 920 are formed on the surface side of the substrate 901. In addition, a gate region 930 may be formed on the substrate 901, and an STI region 940 may be formed within the drift region 910. The STI region may prevent an electric field from concentrating on the edge side of the gate region 930 and below a field plate 960, which will be described later. However, since the STI region 940 is formed from the surface of the substrate 901 to a deep position within the substrate 901, an electric current is compelled to move along the bottom of the STI region 940, resulting in a problem of a current path becoming longer. This becomes a factor that deteriorates on-resistance (Rsp) characteristics of the device 9.

In addition, in the conventional high voltage semiconductor device 9, an insulating pattern 950 and the gate field plate 960 are formed on the upper surface of the gate region 930 and on the drift region 910. The gate field plate 960 is configured to mitigate the electric field concentrated on the surface of the substrate 901. In general, the insulating pattern 950 and the field plate 960 have different left-and-right width sizes (A1 and A2). That is, conventionally, an etching process is performed after forming a mask pattern (not shown) to form the field plate 960, and after forming an additional mask pattern (not shown) to form the insulating pattern 950, the etching process is performed again. This causes a decrease in process efficiency.

To solve the above-mentioned problems, the inventor of the present disclosure proposes a novel high voltage semiconductor device with improved process/structure and a method of manufacturing the same.

### Documents of Related Art

(Patent Document 0001) Korean Patent Application Publication No. 10-2012-0055139 “LDMOS SEMICONDUCTOR DEVICE”

### SUMMARY OF THE INVENTION

The present disclosure has been made to solve the problems of the related art, and an objective of the present disclosure is to provide a high voltage semiconductor device and a method of manufacturing the same seeking to improve on-resistance (Rsp) characteristics of the device by forming a field plate on a substrate and above a gate region, and prevent deterioration of HE-SOA characteristics by forming a thin film-shaped gate field plate below the gate region to mitigate an electric field concentrated below the field plate and on an edge of the gate region.

An objective of the present disclosure is to provide a high voltage semiconductor device and a manufacturing method thereof seeking to prevent on-resistance characteristics from deteriorating by ensuring that a gate field plate has a top-and-bottom thickness of less than half that of the gate region.

An objective of the present disclosure is to provide a high voltage semiconductor device and a manufacturing method thereof seeking to prevent a decrease in overall process efficiency by allowing a field plate and an insulating pattern to be formed together through an etching process using a single mask pattern.

An objective of the present disclosure is to provide a high voltage semiconductor device and a manufacturing method thereof seeking to expand a depletion region by forming a lower well region below a drift region.

The present disclosure may be implemented by an embodiment having the following configuration to achieve the above-described objectives.

According to an embodiment of the present disclosure, there is provided a high voltage semiconductor device, including: a substrate; a drift region disposed on a surface side of the substrate within the substrate; a body region disposed on the surface side of the substrate within the substrate; a drain region disposed within the drift region; a source region disposed within the body region; a gate electrode disposed on the substrate between the source region and the drain region; a gate field plate disposed on a bottom side of the gate electrode on a substrate surface; an insulating pattern disposed on the gate electrode and the gate field plate; and a field plate disposed on the insulating pattern.

According to another embodiment of the present disclosure, in the high voltage semiconductor device, the gate field plate may have a thickness less than half a thickness of a gate region.

According to still another embodiment of the present disclosure, in the high voltage semiconductor device, the gate field plate may have a thickness range of 300 Å or more and 1200 Å or less.

According to still another embodiment of the present disclosure, in the high voltage semiconductor device, the gate field plate may have a thickness range of 800 Å or more and 1000 Å or less.

According to still another embodiment of the present disclosure, in the high voltage semiconductor device, the insulating pattern may have a width size substantially equal to a width size of the field plate.

According to still another embodiment of the present disclosure, in the high voltage semiconductor device, the field plate may be formed with the insulating pattern in a single etching process.

According to still another embodiment of the present disclosure, in the high voltage semiconductor device, a width size of a portion of the insulating pattern in contact with the gate field plate may have a range of 50% or more and 70% or less of the width size of the insulating pattern.

According to still another embodiment of the present disclosure, in the high voltage semiconductor device, the insulating pattern may have a thickness ratio within a range of 1 times or more and 1.2 times or less compared to the gate field plate.

According to still another embodiment of the present disclosure, in the high voltage semiconductor device, the gate field plate may have a thickness ratio within a range of 0.2 times or more and 0.3 times or less compared to the gate electrode.

According to still another embodiment of the present disclosure, the high voltage semiconductor device may further include: an LDD region disposed within the body region.

According to still another embodiment of the present disclosure, in the high voltage semiconductor device, the LDD region may have a shallower depth from the substrate surface within the substrate than a depth of the source region.

According to still another embodiment of the present disclosure, a high voltage semiconductor device of the present disclosure includes: a substrate; a drift region disposed on a surface side of the substrate within the substrate; a body region disposed on the surface side of the substrate within the substrate; a gate electrode disposed on the substrate; a buried layer disposed below the drift region within the substrate; a lower well region disposed between the drift region and the buried layer; a gate field plate disposed on a bottom side of the gate electrode on a surface side of the drift region; an insulating pattern disposed on the gate electrode and the gate field plate; and a field plate disposed on the insulating pattern and having a width size substantially equal to a width size of the insulating pattern.

According to still another embodiment of the present disclosure, in the high voltage semiconductor device, the drift region may have an impurity doped region of a second conductivity type and the lower well region may have an impurity doped region of a first conductivity type.

According to still another embodiment of the present disclosure, in the high voltage semiconductor device, the insulating pattern and the field plate may be formed using a single mask pattern.

According to still another embodiment of the present disclosure, in the high voltage semiconductor device, one end of the field plate and one end of the insulating pattern may be disposed on a same vertical plane, and another opposite end of the field plate and another opposite end of the insulating pattern may be disposed on another same vertical plane.

According to an embodiment of the present disclosure, there is provided a method of manufacturing a high voltage semiconductor device, the method including: forming a drift region on a surface of a substrate within the substrate; forming a body region on the surface of the substrate within the substrate; forming a gate field plate on the surface of the substrate on a drift region side; forming a gate region on the substrate; and forming an insulating pattern and a field plate on the gate region and the gate field plate.

According to another embodiment of the present disclosure, in the method of manufacturing a high voltage semiconductor device, the forming the insulating pattern and the field plate may include: forming an insulating layer on the substrate to cover the gate region and the gate field plate; forming a polysilicon film on the insulating layer; forming a mask pattern on the polysilicon film; and etching the polysilicon film and the insulating layer together using the mask pattern.

According to still another embodiment of the present disclosure, in the method of manufacturing a high voltage semiconductor device, the forming the gate field plate may include: forming a pad oxide film on the substrate; forming a nitride film on the pad oxide film; forming a mask pattern on the nitride film; sequentially etching the nitride film, the pad oxide film, and the surface of the substrate; and growing the etched oxide film through a thermal oxidation process.

According to still another embodiment of the present disclosure, the method of manufacturing a high voltage semiconductor device may further include: forming a drain extension region within the drift region; forming a drain region within the drain extension region; and forming a source region within the body region.

According to still another embodiment of the present disclosure, the method of manufacturing a high voltage semiconductor device may further include: forming an LDD region within the body region before forming the source region.

The present disclosure has the following effects by the above configurations.

According to the present disclosure, on-resistance (Rsp) characteristics of a semiconductor device can be improved by forming a field plate on a substrate and above a gate region, and deterioration of HE-SOA characteristics can be prevented by forming a thin film-shaped gate field plate below the gate region to mitigate an electric field concentrated below the field plate and on an edge of the gate region.

In addition, according to the present disclosure, by ensuring that a gate field plate has a top and bottom thickness of less than half that of the gate region, on-resistance characteristics can be prevented from deteriorating.

In addition, according to the present disclosure, by allowing a field plate and an insulating pattern to be formed together through an etching process using a single mask pattern, a decrease in overall process efficiency can be prevented.

Furthermore, according to the present disclosure, by forming a lower well region below a drift region, a depletion region can be expanded.

Meanwhile, it should be added that even if effects are not explicitly mentioned herein, the effects described in the following specification expected by the technical features of the present disclosure and their potential effects are treated as if they were described in the specification of the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view showing a conventional high voltage semiconductor device;

FIG. 2 is a cross-sectional view showing a high voltage semiconductor device according to an embodiment of the present disclosure; and

FIGS. 3 to 19 are cross-sectional views showing a method of manufacturing a high voltage semiconductor device according to an embodiment of the present disclosure.

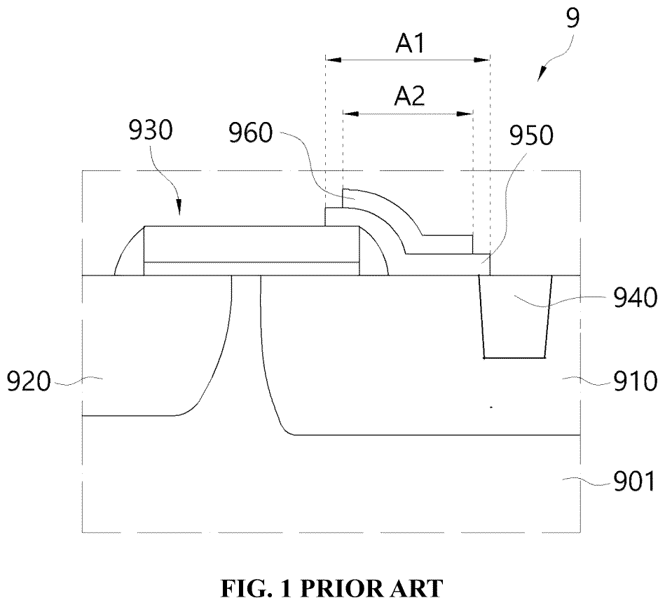

### DETAILED DESCRIPTION OF THE INVENTION

Hereinafter, embodiments of the present disclosure will be described in more detail with reference to the accompanying drawings. The embodiments of the present disclosure may be modified in various forms, and the scope of the present disclosure should not be construed as being limited to the following embodiments, but should be construed based on the matters described in the claims. In addition, these embodiments are only provided for reference in order to more completely explain the present disclosure to those of ordinary skill in the art.

Hereinafter, it should be noted that when one component (or layer) is described as being disposed on another component (or layer), one component may be disposed directly on another component, or another component(s) or layer(s) may be located between the components. In addition, when one component is expressed as being directly disposed on or above another component, no other component(s) are located between the components. Moreover, being located on “top”, “upper”, “lower”, “top”, “bottom”, or “one (first) side” or “side” of a component means a relative positional relationship.

The terms first, second, third, etc. may be used to describe various items such as various components, regions and/or parts. However, the items are not limited by these terms.

In addition, it should be noted that, where certain embodiments are otherwise feasible, certain process sequences may be performed other than those described below. For example, two processes described in succession may be performed substantially simultaneously or in the reverse order.

The term a metal oxide semiconductor (MOS) used below is a general term, and “M” is not limited to only metal and may be formed of various types of conductors. Also, “S” may be a substrate or a semiconductor structure, and “O” is not limited to oxide and may include various types of organic or inorganic materials.

In addition, the conductivity type or doped region of the components may be defined as “p-type” or “n-type” according to the main carrier characteristics, but this is only for convenience of description, and the technical spirit of the present disclosure is not limited to what is illustrated. For example, hereinafter, “p-type” or “n-type” will be used as more general terms “first conductivity type” or “second conductivity type”, and here, the first conductivity type means p-type, and the second conductivity type means n-type.

Furthermore, it should be understood that “high concentration” and “low concentration” expressing the doping concentration of the impurity region mean the relative doping concentration of one component and another component.

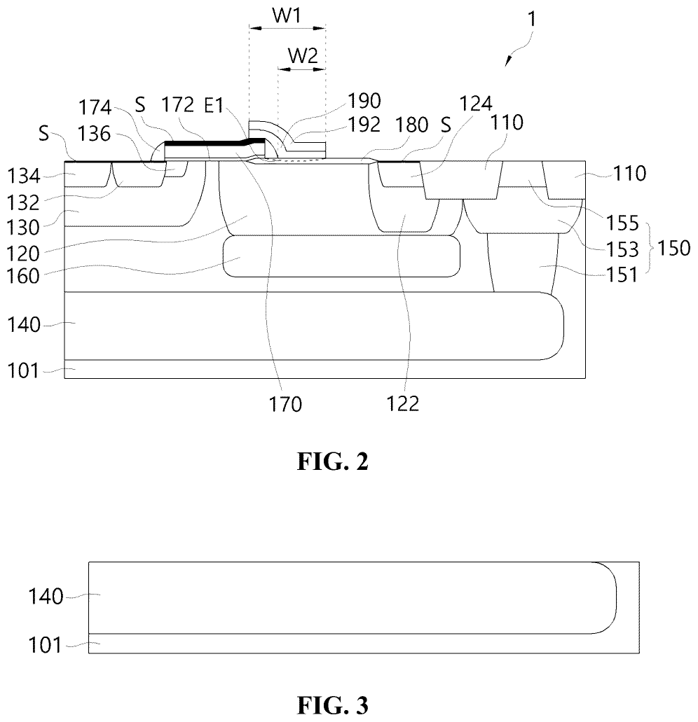

FIG. 2 is a cross-sectional view showing a high voltage semiconductor device according to an embodiment of the present disclosure.

Hereinafter, a high voltage semiconductor device 1 according to an embodiment of the present disclosure will be described in detail with reference to the accompanying drawings. The above “high voltage semiconductor device” may be, for example, an LDMOS device.

Referring to FIG. 2, the present disclosure relates to a high voltage semiconductor device 1 and, more particularly, to a high voltage semiconductor device seeking to improve on-resistance (Rsp) characteristics of the device by forming a field plate on a substrate and above a gate region, and prevent deterioration of HE-SOA characteristics by forming a thin film-shaped gate field plate below the gate region to mitigate an electric field concentrated below the field plate and on an edge of the gate region.

First, a substrate 101 may be formed in the high voltage semiconductor device 1 according to an embodiment of the present disclosure. A well region used as an active region may be formed in the substrate 101, and the active region may be defined by a device isolation layer 110. The substrate 101 may be, for example, a substrate doped with impurities of the first conductivity type, may be a P-type diffusion region disposed in a substrate, or may include a P-type epitaxial layer epitaxially grown on a substrate, and the scope of the present disclosure is not limited by specific examples. The device isolation layer 110 may be formed by a shallow trench isolation (STI) process.

In addition, a drift region 120 may be formed on the surface side of the substrate 101. The drift region 120 is, for example, an impurity doped region of the second conductivity type, and may be spaced apart from a body region 130 to be described later, or may be in contact with the body region 130, but there is no particular limitation thereon. When the doping concentration in the drift region 120 is below a certain level, the on-resistance characteristics are deteriorated. On the contrary, when the doping concentration is increased above a certain level, the on-resistance characteristics are improved, but breakdown voltage characteristics are deteriorated, thus it is desirable to form an impurity region having an appropriate level of doping concentration in consideration of these characteristics.

A drain extension region 122 may be formed within the drift region 120. That is, the drain extension region 122 may be surrounded by the drift region 120. The drain extension region 122 is, for example, an impurity doped region of the second conductivity type, and is preferably a doped region with a higher concentration of impurities than the drift region 120. The breakdown voltage characteristics of the device 1 may be improved by the drain extension region 122, but it should be noted that the drain extension region 122 is not an essential component of the present disclosure.

A drain region 124 may be formed within the drain extension region 122 or within the drift region 120. The drain region 124 is a region formed on the surface area of the substrate 101 within the drift region 120 and may be an impurity doped region of the second conductivity type. The drain region 124 is preferably a doped region with a higher concentration of impurities compared to the drain extension region 122 and the drift region 120. The drain region 124 may be electrically connected to a drain electrode (not shown).

The body region 130 may be formed on the surface side of the substrate. As previously described, the body region 130 may be spaced apart from drift region 120, or may be in contact with the drift region 120. The body region 130 may be an impurity doped region of the first conductivity type.

In addition, a source region 132 and a body contact region 134 may be formed on the surface side of the substrate within the on the surface side of the substrate. The source region 132 and the body contact region 134 may be adjacent to each other or may be formed such that at least one side of the source region 132 and one side of the body contact region 134 contact each other. At this time, the source region 132 is a region doped with a high concentration of impurities of the second conductivity type, and the body contact region 134 is an impurity doped region of the first conductivity type and may be a region doped with a higher concentration of impurities than the body region 130. The source region 132 may be electrically connected to a source electrode (not shown).

A lightly doped drain (LDD) region 136 may be further formed within the body region 130. The LDD region 136 is an impurity doped region of the second conductivity type and is preferably a doped region with a lower concentration of impurities compared to the source region 132. The LDD region 136 may be formed to contact the source region 132 and/or the body contact region 134 below the gate region 170. In addition, the LDD region 136 is preferably formed from the surface of the substrate 101 to a shallower depth within the substrate 101 than the source region 132 and/or the body contact region 134.

A buried layer 140 may be formed in a position deeper than the drift region 120 and the body region 130 within the substrate 101. The buried layer 140 is an impurity doped region of the second conductivity type, is formed at the bottom of the substrate 101, and may prevent electrons generated by a voltage applied to the drain electrode from flowing into the substrate 101. That is, the buried layer 140 is capable of suppressing punch-through current.

A guard ring 150 may be formed on the side connected to the buried layer 140. One side of the guard ring 150 may be spaced apart from the drift region 120, or may be in contact with the drift region 120, but there is no particular limitation thereon. The guard ring 150 may include a first well region 151, a second well region 153, and a high concentration region 155 from the bottom to the top.

The first well region 151 is an impurity doped region connected to the buried layer 140 and the second well region 153, and may be, for example, an impurity doped region of the second conductivity type. As an example, the bottom of the first well region 151 may be connected to the upper side of the buried layer 140, and the upper side of the first well region 151 may be connected to the bottom of the second well region 153.

The second well region 153 is an impurity doped region connected to the first well region 151, and may be, for example, an impurity doped region of the second conductivity type. As an example, the bottom of the second well region 153 may be connected to the upper side of the first well region 151.

The high concentration region 155 is an impurity doped region formed in the second well region 153 on the surface side of the substrate 101, and may be, for example, an impurity doped region of the second conductivity type. In addition, it is preferable that the high concentration region 155 is a region doped with a higher concentration of impurities than the second well region 153. The high concentration region 155 may be formed to be spaced apart from the adjacent drain region 124 by the device isolation layer 110.

As such, due to the guard ring 150 that includes the first well region 151, the second well region 153, and the high concentration region 155, isolation characteristics of the device 1 may be improved, leakage current reduced, and SOA improved.

A lower well region 160 may be formed below the drift region 120 within the substrate 101. For example, the lower well region 160 is formed between the drift region 120 and the buried layer 140 and may be formed to contact the bottom of the drift region 120. The lower well region 160 may perform the function of expanding a depletion region. It should be noted that the lower well region 160 is not an essential component of the present disclosure.

A gate electrode 170 may be formed on the substrate 101. The gate electrode 170 may be formed between the drain region 124 and the source region 132 on the substrate 101. The gate electrode 170 is located on a channel region, and the channel region may be turned on or off by a gate voltage applied to the gate electrode 170. The gate electrode 170 may include any one of conductive polysilicon, metal, conductive metal nitride, and a combination thereof, and may be formed by a CVD, PVD, ALD, MOALD, or MOCVD process or the like.

In addition, a gate insulating layer 172 is formed between the gate electrode 170 and the surface of the substrate 101 and along the sidewall of the gate electrode 170. The gate insulating layer 172 may include any one of a silicon oxide film, a high dielectric film, and a combination thereof. The gate insulating layer 172 may be formed by an ALD, CVP, or PVD process.

Sidewalls of the gate electrode 170 and the gate insulating layer 172 may be covered with a gate spacer 174, and the gate spacer 174 may include any one of an oxide film, a nitride film, and a combination thereof. The described gate electrode 170, the gate insulating layer 172, and the gate spacer 174 will be included in and referred to as the “gate region”.

In addition, a gate field plate 180 may be formed on the surface side of the substrate 101. To be specific, the gate field plate 180 may be formed to extend from the bottom edge side of the gate region to the adjacent drain region 124 or to the side adjacent to the drain region 124. The gate field plate 180 may be formed by a local oxidation of silicon (LOCOS) process. Due to the gate field plate 180, it is possible to prevent an electric field from being concentrated on the edge side of the gate region and below a field plate 192.

In an embodiment of the present disclosure, the gate field plate 180 has a slight top and bottom thickness. The gate field plate 180 preferably has a top and bottom thickness of less than half the top and bottom thickness of the gate region. To be specific, the gate field plate 180 preferably has a thickness of, for example, more than 300 Å and less than 1200 Å, and preferably more than 800 Å and less than 1000 Å. By forming the gate field plate 180 thin like this, compared to when the gate field plate 180 is not formed, a current movement path may be prevented as much as possible from becoming longer, and thus the on-resistance (Rsp) characteristics of the device 1 may be prevented from being deteriorated.

An insulating pattern 190 may be formed on the gate electrode 170 and the gate field plate 180. For example, the insulating pattern 190 may have one end thereof located on the top surface of the gate electrode 170 and extend onto the top surface of the gate field plate 180. The insulating pattern 190 may include any one of a silicon oxide film, a high dielectric film, and a combination thereof, but the scope of the present disclosure is not limited thereto. The bottom of the insulating pattern 190 may be formed in a shape that corresponds to the upper surfaces of the gate electrode 170 and the gate field plate 180 directly below the insulating pattern 190.

In addition, the field plate 192 may be formed on the insulating pattern 190. The field plate 192 is, for example, a polysilicon film, and may be formed into a shape that substantially corresponds to the insulating pattern 190. For example, the field plate 192 may have one end thereof vertically overlap with the gate electrode 170, and the other end thereof vertically overlap with the gate field plate 180. It is preferable that the insulating pattern 190 and the field plate 192 have substantially the same width W1. To be specific, one end of the insulating pattern 190 and one end of the field plate 192 on the gate electrode 170 may be located substantially on the same vertical plane, and the other end of the insulating pattern 190 and the other end of the field plate 192 on the gate field plate 180 may also be located substantially on the same vertical plane. In other words, the field plate 192 may have a width size WI substantially the same as that of the insulating pattern 190.

In addition, a width size W2 of the portion of the insulating pattern 190 located immediately above the gate field plate 180 may have a ratio within the range of approximately 50% or more and 70% or less of the width size WI of the entire insulating pattern 190. The insulating pattern 190 may have a top-to-bottom thickness ratio within the range of approximately 1 times or more and 1.2 times or less compared to the gate field plate 180. The gate field plate 192 may have a top-to-bottom thickness ratio within the range of approximately 0.2 times or more and 0.3 times or less compared to the gate electrode 170.

A silicide layer S may be formed on the upper surfaces of the drain region 124, the source region 132, the body contact region 134, and the gate electrode 170. The silicide layer S may be formed of, for example, a metal film. The silicide layer S may be formed by a self-aligned silicide process to improve contact resistance and thermal stability, and may be a cobalt (Co), nickel (Ni), or titanium (Ti) metal film for example.

FIGS. 3 to 19 are cross-sectional views showing a method of manufacturing a high voltage semiconductor device according to an embodiment of the present disclosure.

Hereinafter, a method of manufacturing a high voltage semiconductor device according to an embodiment of the present disclosure will be described in detail with reference to the accompanying drawings.

Referring to FIG. 3, first, a buried layer 140 is formed on the surface side of the substrate 101. The buried layer 140 is an impurity doped region of the second conductivity type and may be formed on the surface of the substrate 101 by an ion implantation process.

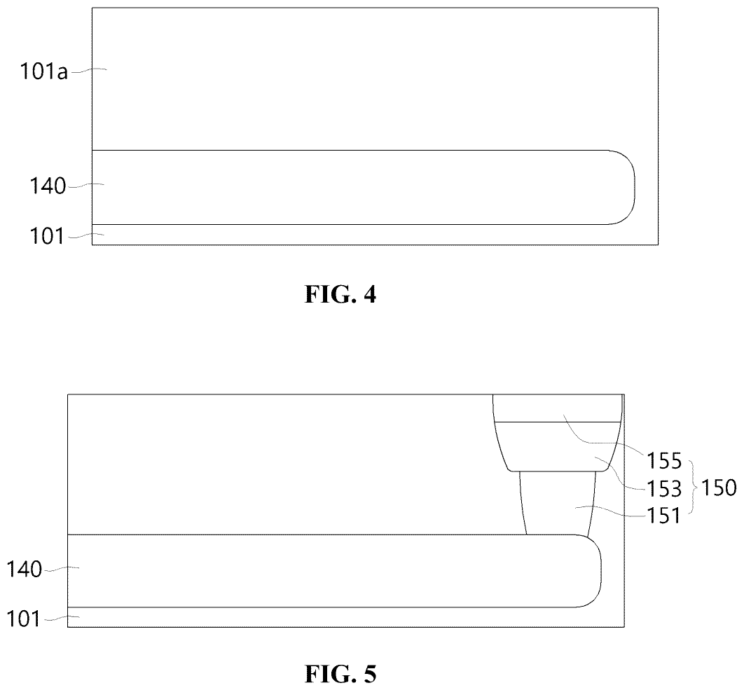

Then, referring to FIG. 4, an epitaxial layer 101a is formed on the substrate 101 on which the buried layer 140 is formed. Hereinafter, “substrate” is understood as a substrate on which the epitaxial layer 101a is grown, including the epitaxial layer 101a.

Referring to FIG. 5, in the subsequent process, a guard ring 150 is formed within the substrate 101. The guard ring 150 may include a first well region 151, a second well region 153, and a high concentration region 155, and may be formed by performing an ion implantation process by utilizing a mask pattern (not shown).

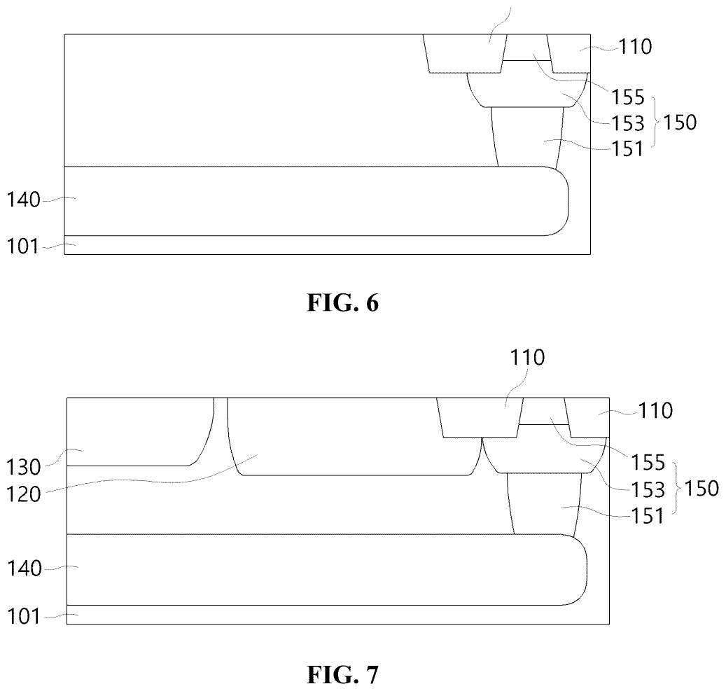

Thereafter, referring to FIG. 6, a device isolation layer 110 is formed from the surface side of the substrate 101 to a predetermined depth. As previously described, the device isolation layer 110 may be formed by a trench isolation process. In addition, an active region may be defined by the device isolation layer 110.

Thereafter, referring to FIG. 7, a drift region 120 and a body region 130 may be formed. The drift region 120 and the body region 130 are formed by individual processes, and may be formed by an ion implantation process using a mask pattern (not shown) in each process.

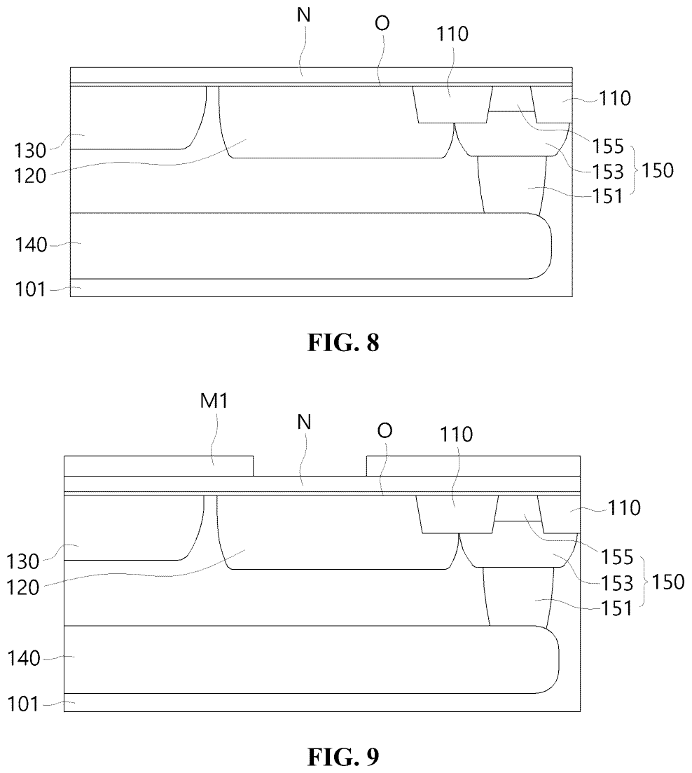

Afterwards, a gate field plate 180 may be formed on the surface of the substrate 101 on the drift region 120 side. The gate field plate 180 may be formed by a LOCOS process, which will be explained in detail. Referring to FIG. 8, a pad oxide film O is formed on the substrate 101, and then a nitride film N is formed on the pad oxide film. The pad oxide film O serves as an intermediate buffer because the difference in thermal expansion coefficient between the nitride film N and the substrate 101 is large, and the nitride film N may be made of Si3N4, etc.

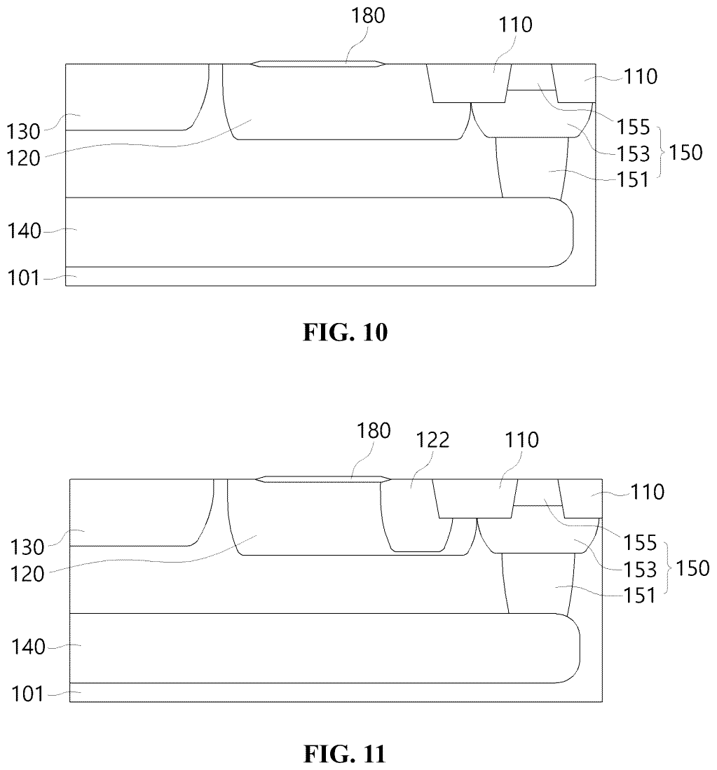

Thereafter, referring to FIG. 9, after forming a mask pattern M1 on the nitride film N, an open side of the pattern M1 is etched. That is, the surfaces of the nitride film N, pad oxide film O, and substrate 101 may be sequentially etched. Thereafter, referring to FIG. 10, an oxide film is grown by a thermal oxidation process. Thereby the gate field plate 180 may be formed. As previously described, the gate field plate 180 preferably has a top and bottom thickness of less than half the top and bottom thickness of a gate region. To be specific, the gate field plate 180 preferably has a thickness of, for example, more than 300 Å and less than 1200 Å, and preferably more than 800 Å and less than 1000 Å.

Thereafter, referring to FIG. 11, a drain extension region 122 may be formed within the drift region 120. The drain extension region 122 may be formed by an ion implantation process using a mask pattern (not shown). However, as previously described, it should be noted that the drain extension region 122 is not an essential component of the present disclosure.

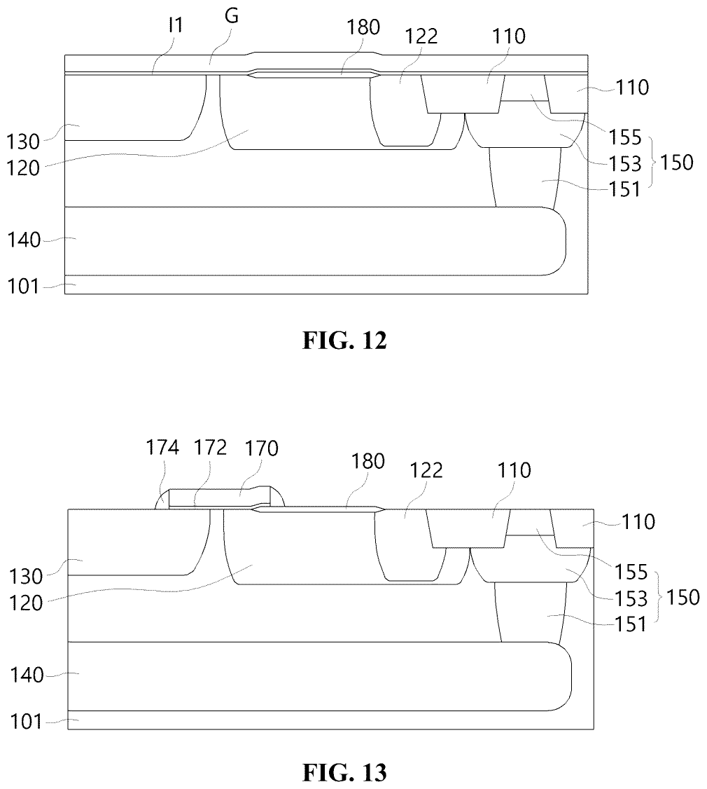

Afterwards, the gate region may be formed, which will be explained in detail. Referring to FIG. 12, a first insulating layer I1 may be formed on the substrate 101 on which the gate field plate 180 is formed, and a gate layer G may be formed on the first insulating layer I1. The first insulating layer I1 may include any one of a silicon oxide film, a high dielectric film, and a combination thereof. The gate layer G may include any one of conductive polysilicon, metal, conductive metal nitride, and a combination thereof.

Thereafter, referring to FIG. 13, after forming a mask pattern (not shown) on the gate layer G, the gate layer G and the first insulating layer Il are etched. Thereby a gate electrode 170 and a gate insulating layer 172 may be completed. In addition, a second insulating layer (not shown) is deposited on the side of the gate electrode 170, for example, using a chemical vapor deposition (CVD) process, and a gate spacer 174 may be formed on each side of the gate electrode 170 by performing anisotropic dry etching.

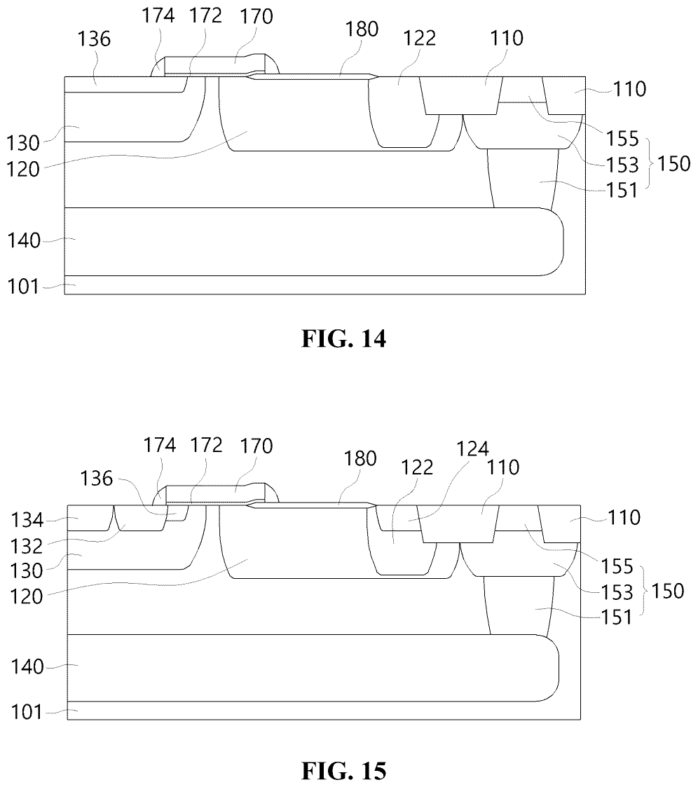

Referring to FIG. 14, after forming the gate region, an LDD region 136 may be formed. The LDD region 136 may be formed by an ion implantation process using the gate spacer 174 as an ion implantation mask, or may be formed using a separate mask pattern (not shown), but there is no particular limitation thereon.

Thereafter, referring to FIG. 15, a drain region 124 and a source region 132 may be formed. That is, the drain region 124, which is a high concentration impurity doped region of the second conductivity type, may be formed by an ion implantation process in the drift region 120 or in the drain expansion region 122, and the source region 132, which is a high concentration impurity doped region of the second conductivity type, may be formed in the body region 130. Once the source region 132 is formed, a body contact region 134, which is a high concentration impurity doped region of the first conductivity type, may be formed by an ion implantation process in the body region 130.

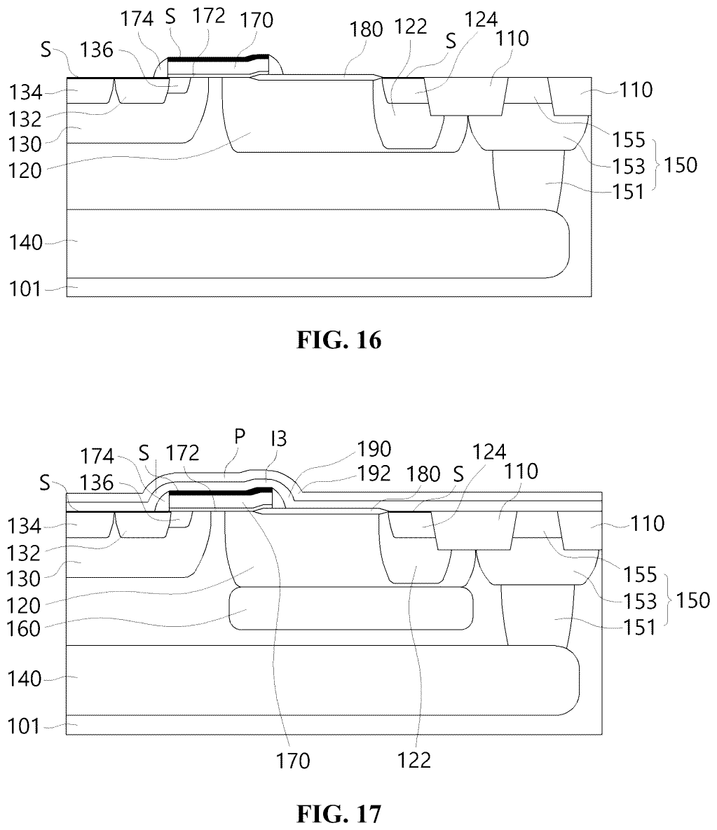

Thereafter, referring to FIG. 16, in order to improve contact resistance and thermal stability, a self-aligned silicide (salicide) process is performed using a metal film composed of cobalt (Co), nickel (Ni), or titanium (Ti), etc., to form a silicide layer S on the upper surfaces of the drain region 124, the source region 132, the body contact region 134, and the gate electrode 170.

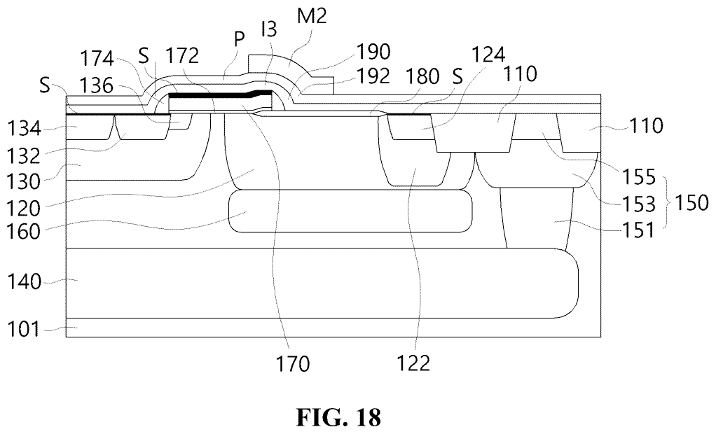

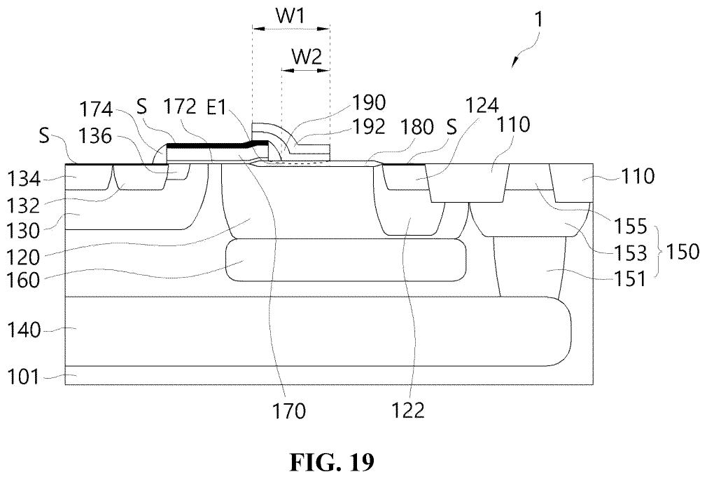

Afterwards, an insulating pattern 190 is formed on at least one upper surface of the gate electrode 170 and on at least one upper surface of the gate field plate 180, and a field plate 192 is formed on the insulating pattern 190, which will described in detail. Referring to FIG. 17, a third insulating layer 13 is formed on the substrate 101 to cover the gate electrode 170 and the gate field plate 180. Then, a polysilicon film P is formed on the third insulating layer I3. Thereafter, referring to FIGS. 18 and 19, after forming a mask pattern M2 on the polysilicon film P, an etching process may be performed to form the insulating pattern 190 and the field plate 192 substantially at the same time. As such, the present disclosure has the advantage of using only the single mask pattern M2 when forming the insulating pattern 190 and the field plate 192. Thus, although the mask pattern MI is added when forming the gate field plate 180, since the single mask pattern M2 is used when forming the insulating pattern 190 and the field plate 192, the total number of masks is the same compared to the case of not utilizing the gate field plate 180, which is a feature of the present disclosure.

Due to the above-mentioned process, the field plate 192 may have a width WI that is substantially the same as that of the insulating pattern 190 (see FIG. 19). In addition, a width size W2 of the portion of the insulating pattern 190 located immediately above the gate field plate 180 may have a ratio within the range of approximately 50% or more and 70% or less of the width size WI of the entire insulating pattern 190. The insulating pattern 190 may have a top-to-bottom thickness ratio within the range of approximately 1 times or more and 1.2 times or less compared to the gate field plate 180. The gate field plate 192 may have a top-to-bottom thickness ratio within the range of approximately 0.2 times or more and 0.3 times or less compared to the gate electrode 170.

The above detailed description is illustrative of the present disclosure. In addition, the above description shows and describes preferred embodiments of the present disclosure, and the present disclosure can be used in various other combinations, modifications, and environments. That is, changes or modifications are possible within the scope of the concept of the disclosure disclosed herein, the scope equivalent to the written disclosure, and/or within the scope of skill or knowledge in the art. The above-described embodiment describes the best state for implementing the technical idea of the present disclosure, and various changes required in the specific application field and use of the present disclosure are possible. Accordingly, the detailed description of the present disclosure is not intended to limit the present disclosure to the disclosed embodiments.

What is claimed is:

1. A high voltage semiconductor device, comprising:
a substrate;
a drift region disposed on a surface side of the substrate within the substrate;
a body region disposed on the surface side of the substrate within the substrate;
a drain region disposed within the drift region;
a source region disposed within the body region;
a gate electrode disposed on the substrate between the source region and the drain region;
a gate field plate disposed on a bottom side of the gate electrode on a substrate surface;
an insulating pattern disposed on the gate electrode and the gate field plate; and
a field plate disposed on the insulating pattern.

2. The high voltage semiconductor device of claim 1, wherein the gate field plate has a thickness less than half a thickness of a gate region.

3. The high voltage semiconductor device of claim 1, wherein the gate field plate has a thickness range of 300 Å or more and 1200 Å or less.

4. The high voltage semiconductor device of claim 1, wherein the gate field plate has a thickness range of 800 Å or more and 1000 Å or less.

5. The high voltage semiconductor device of claim 1, wherein the insulating pattern has a width size substantially equal to a width size of the field plate.

6. The high voltage semiconductor device of claim 5, wherein the field plate is formed with the insulating pattern in a single etching process.

7. The high voltage semiconductor device of claim 5, wherein a width size of a portion of the insulating pattern in contact with the gate field plate has a range of 50% or more and 70% or less of the width size of the insulating pattern.

8. The high voltage semiconductor device of claim 5, wherein the insulating pattern has a thickness ratio within a range of 1 times or more and 1.2 times or less compared to the gate field plate.

9. The high voltage semiconductor device of claim 5, wherein the gate field plate has a thickness ratio within a range of 0.2 times or more and 0.3 times or less compared to the gate electrode.

10. The high voltage semiconductor device of claim 1, further comprising:
an LDD region disposed within the body region.

11. The high voltage semiconductor device of claim 10, wherein the LDD region has a shallower depth from the substrate surface within the substrate than a depth of the source region.

12. A high voltage semiconductor device, comprising:
a substrate;
a drift region disposed on a surface side of the substrate within the substrate;
a body region disposed on the surface side of the substrate within the substrate;
a gate electrode disposed on the substrate;
a buried layer disposed below the drift region within the substrate;
a lower well region disposed between the drift region and the buried layer;
a gate field plate disposed on a bottom side of the gate electrode on a surface side of the drift region;
an insulating pattern disposed on the gate electrode and the gate field plate; and
a field plate disposed on the insulating pattern and having a width size substantially equal to a width size of the insulating pattern.

13. The high voltage semiconductor device of claim 12, wherein the drift region has an impurity doped region of a second conductivity type and the lower well region has an impurity doped region of a first conductivity type.

14. The high voltage semiconductor device of claim 12, wherein the insulating pattern and the field plate are formed using a single mask pattern.

15. The high voltage semiconductor device of claim 14, wherein one end of the field plate and one end of the insulating pattern are disposed on a same vertical plane, and another opposite end of the field plate and another opposite end of the insulating pattern are disposed on another same vertical plane.

16. A method of manufacturing a high voltage semiconductor device, the method comprising:
forming a drift region on a surface of a substrate within the substrate;
forming a body region on the surface of the substrate within the substrate;
forming a gate field plate on the surface of the substrate on a drift region side;
forming a gate region on the substrate; and
forming an insulating pattern and a field plate on the gate region and the gate field plate.

17. The method of claim 16, wherein the forming the insulating pattern and the field plate comprises:
forming an insulating layer on the substrate to cover the gate region and the gate field plate;
forming a polysilicon film on the insulating layer;
forming a mask pattern on the polysilicon film; and
etching the polysilicon film and the insulating layer together using the mask pattern.

18. The method of claim 16, wherein the forming the gate field plate comprises:
forming a pad oxide film on the substrate;
forming a nitride film on the pad oxide film;
forming a mask pattern on the nitride film;
sequentially etching the nitride film, the pad oxide film, and the surface of the substrate; and
growing the etched oxide film through a thermal oxidation process.

19. The method of claim 16, further comprising:
forming a drain extension region within the drift region;
forming a drain region within the drain extension region; and
forming a source region within the body region.

20. The method of claim 19, further comprising:
forming an LDD region within the body region before forming the source region.
